(19) United States
(12) Patent Application Publication
(10) Pub. No.: US 2026/0118787 A1
(43) Pub. Date: Apr. 30, 2026

(54) ENHANCED ALIGNMENT APPARATUS FOR LITHOGRAPHIC SYSTEMS

(71) Applicant: ASML Netherlands B.V., Veldhoven (NL)

(72) Inventor: Simon Reinald Huisman, Eindhoven (NL)

(21) Appl. No.: 18/865,955

(22) PCT Filed: Jul. 5, 2023
(86) PCT No.: PCT/EP2023/068610

§ 371 Date: Nov. 14, 2024

Related U.S. Application Data
(60) Provisional application No. 63/390,509, filed on Jul. 19, 2022.

(51) Int. Cl. G03F 9/00

(52) U.S. Cl. CPC G03F 9/7088; G03F 9/7049

(57) ABSTRACT

Disclosed is a metrology apparatus in which some of the measurement radiation that has interacted with a mark is split into channels or arms and then each channel or arm is spatially separated. In some versions the alignment information comprises polarization channel intensity information. In other versions the alignment information comprises color channel intensity information.

### CROSS-REFERENCE TO RELATED APPLICATIONS

This application claims priority of U.S. application 63/390,509 which was filed on Jul. 19, 2022 and which is incorporated herein in its entirety by reference.

### FIELD

The subject matter disclosed and described herein relates to an apparatus for obtaining alignment information in a lithographic system.

### BACKGROUND

A lithographic apparatus applies a desired pattern onto a substrate, usually onto a target portion of the substrate. A lithographic apparatus can be used, for example, in the manufacture of integrated circuits (ICs). In such an application, a patterning device, which is referred to as a mask or a reticle, may be used to form a circuit pattern on an individual layer of the IC. This pattern can be transferred onto a target portion (e.g. including part of, one, or several dies) on the substrate (e.g. a silicon wafer).

Transfer of the pattern is typically accomplished by imaging onto a layer of radiation-sensitive material (resist) provided on the substrate. In general, a single substrate will contain a network of adjacent target portions that are successively patterned.

In optical step-and-scan lithography tools, alignment is performed i) to align the mask relative to the mask stage, ii) to align the wafer relative to the wafer stage, and iii) to align the mask and the wafer relative to each other. One or more marks, e.g., alignment marks, are generally provided on the substrate to control alignment to place device features accurately on the substrate. Different types of marks and different types of systems are known from different times and different manufacturers. Types of alignment marks include bidirectional fine (BF) alignment marks and smaller format alignment marks such as combined bidirectional (CB) alignment marks.

Alignment data is obtained by an alignment sensor, for example a SMASH (SMart Alignment Sensor Hybrid) sensor, as described in U.S. Pat. No. 6,961,116, issued Nov. 1, 2005, and titled “Lithographic Apparatus, Device Manufacturing Method, and Device Manufactured Thereby” that employs a self-referencing interferometer (SRI) with a single detector and four different wavelengths, and extracts an alignment signal in software. Another system is ATHENA (Advanced Technology using High order ENhancement of Alignment), as described in U.S. Pat. No. 6,297,876, issued Oct. 2, 2001, and titled “Lithographic Projection Apparatus with an Alignment System for Aligning Substrate on Mask,” which directs each of seven diffraction orders to a dedicated detector. Yet another system uses a sensor as described in U.S. Pat. No. 10,508,906, issued Dec. 17, 2019, and titled “Method of Measuring a Parameter and Apparatus,” which uses multiple polarizations per available signal (color).

All patent applications, patents, and printed publications cited herein are incorporated herein by reference in their entireties, except for any definitions, subject matter disclaimers or disavowals, and except to the extent that the incorporated material is inconsistent with the express disclosure herein, in which case the language in this disclosure controls.

For the benefit of improving throughput there is an impetus for acquiring alignment information in an uncomplicated and rapid fashion. This results in a need to obtain multiple types of data in parallel, i.e., at the same time, and to make that data available in a similar fashion. For systems that are not image-based it would be advantageous to multiple channels of polarization intensity data available at the same time and in a form readily accessible to the system.

### SUMMARY

The following presents a concise summary of one or more embodiments in order to provide an understanding of the present invention. This summary is not an extensive overview of all contemplated embodiments and is not intended to identify key or critical elements of the described embodiments nor delineate the full scope of any described embodiments. Its sole purpose is to present some concepts relating to one or more embodiments in a succinct form as a prelude to the more detailed description that is presented later.

According to one aspect of an embodiment there is disclosed a metrology device comprising a beam separation element arranged to receive measurement radiation that has interacted with a mark and to cause a first fraction of the measurement radiation to propagate in a first channel and to cause a second fraction of the measurement radiation to propagate in a second channel, the second fraction having a different optical property than the first fraction.

The metrology device also comprises a first channel separation element arranged in the first channel to spatially separate a plurality of first channel constituents of the first fraction, a first channel optical element arranged to focus the first channel constituents, and a first multicore fiber having a plurality of cores respectively corresponding to ones of the plurality of first channel constituents arranged at a focal plane of the first channel optical element. The metrology device also comprises a second channel separation element arranged in the second channel to spatially separate a plurality of second channel constituents of the second fraction, a second channel optical element arranged to focus the second channel constituents, and a second multicore fiber having a plurality of cores respectively corresponding to ones of the plurality of second channel constituents arranged at a focal plane of the second channel optical element.

The optical property may be polarization or color. The first channel constituents and the second channel constituents may comprise diffraction orders.

The beam separation element may comprise a polarizing beam splitter arranged to receive the measurement radiation and to cause the first fraction of the received radiation having a first polarization to propagate in the first channel and to cause the second fraction of the received radiation having a second polarization to propagate in the second channel.

The first channel separation element may comprise a first segmented optical wedge and the second channel separation element may comprise a second segmented optical wedge. The first segmented optical wedge and the second segmented optical wedge may be transmissive or reflective.

The first channel separation element may comprise a first segmented lens or a grating and the second channel separation element may comprise a second segmented lens or a grating.

The first multicore fiber may comprise one of multimode fiber cores, single mode fiber cores, and a combination of multimode fiber cores and single mode fiber cores and the second multicore fiber may comprise one of multimode fiber cores, single mode fiber cores, and a combination of multimode fiber cores and single mode fiber cores.

At least one of the first channel separation element and the second channel separation element may be configurable. At least one of a position and an orientation of receiving ends of at least one of the first multicore fiber and the second multicore fiber may be configurable.

According to another aspect of an embodiment there is disclosed a metrology device comprising a spatial separation element arranged to receive measurement radiation that has interacted with a mark and to spatially separate constituents of the measurement radiation and a beam separation element arranged to receive the spatially separated measurement radiation and to cause a first fraction of the spatially separated measurement radiation to propagate in a first channel and to cause a second fraction of the spatially separated measurement radiation to propagate in a second channel, the second fraction having a different optical property than the first fraction.

The metrology device may also comprise a first channel optical element arranged to focus the first fraction and a first multicore fiber having a plurality of cores respectively corresponding to constituents in the first channel arranged at a focal plane of the first channel optical element. The metrology device also comprises a second channel optical element arranged to focus the second fraction and a second multicore fiber having a plurality of cores respectively corresponding to constituents in the second channel arranged at a focal plane of the second channel optical element.

The optical property for this additional aspect may be polarization or color. The first channel constituents and the second channel constituents for this additional aspect may comprise diffraction orders.

The first channel separation element for this additional aspect may comprise a first segmented optical wedge and the second channel separation element may comprise a second segmented optical wedge. The first segmented optical wedge and the second segmented optical wedge may be transmissive or reflective.

The first channel separation element for this additional aspect may comprise a first segmented lens or a grating and the second channel separation element may comprise a second segmented lens or a grating.

The first channel separation element may comprise a first segmented optical wedge and the second channel separation element may comprise a second segmented optical wedge. The first segmented optical wedge and the second segmented optical wedge may be transmissive or reflective.

At least one of the first channel separation element and the second channel separation element may be configurable. At least one of a position and an orientation of receiving ends of at least one of the first multicore fiber and the second multicore fiber may be configurable.

According to another aspect of an embodiment there is disclosed a metrology device comprising a polarizing beam splitter arranged to receive measurement radiation that has interacted with a mark and to cause a first fraction of the measurement radiation having a first polarization to propagate in a first arm and to cause a second fraction of the received radiation having a second polarization to propagate in a second arm. The first arm may comprise a polarizing beam splitter arranged to receive the first fraction and to split off first polarized radiation from the first fraction, first optics arranged to receive the first polarized radiation and to spatially separate and focus the first polarized radiation, and a first multicore fiber arranged at a focal plane of the first optics. The second arm may comprise second optics arranged to receive the second fraction and to spatially separate and focus the second fraction and a second multicore fiber arranged at a focal plane of the second optics.

The metrology device may further comprise a polarization rotation element positioned in the first arm between the polarizing beam splitter and the first optics.

The first optics may comprise a first segmented optical wedge and the second optics may comprise a second segmented optical wedge. The first segmented optical wedge may be transmissive or reflective. The first optics may comprise a segmented lens. The first optics may comprise a grating.

The first channel separation element may comprise a first segmented optical wedge and the second channel separation element may comprise a second segmented optical wedge. The first segmented optical wedge and the second segmented optical wedge may be transmissive or reflective.

At least one of the first channel separation element and the second channel separation element may be configurable. At least one of a position and an orientation of receiving ends of at least one of the first multicore fiber and the second multicore fiber may be configurable.

According to another aspect of an embodiment there is disclosed a metrology device comprising a beam separation element arranged to receive measurement radiation that has interacted with a mark and to cause a first fraction of the measurement radiation to propagate in a first channel and to cause a second fraction of the measurement radiation to propagate in a second channel, the second fraction having a different optical property than the first fraction. The metrology device also comprises a first channel separation element arranged in the first channel to spatially separate a plurality of first channel constituents of the first fraction, a first channel optical element arranged to focus the first channel constituents, and a first segmented detector having a plurality of first detector segments respectively corresponding to ones of the plurality of first channel constituents arranged at a focal plane of the first channel optical element. The metrology device also comprises a second channel separation element arranged in the second channel to spatially separate a plurality of second channel constituents of the second fraction, a second channel optical element arranged to focus the second channel constituents, and a second segmented detector having a plurality of second detector segments respectively corresponding to ones of the plurality of second channel constituents arranged at a focal plane of the second channel optical element.

The optical property may be polarization or color. The first channel constituents and the second channel constituents may comprise diffraction orders.

The beam separation element may comprise a polarizing beam splitter arranged to receive the measurement radiation and to cause the first fraction of the received radiation having a first polarization to propagate in the first channel and to cause the second fraction of the received radiation having a second polarization to propagate in the second channel.

The first channel separation element may comprise a first segmented optical wedge and the second channel separation element may comprise a second segmented optical wedge. The first segmented optical wedge and the second segmented optical wedge may be transmissive or reflective.

The first channel separation element may comprise a first segmented lens or a grating and the second channel separation element may comprise a second segmented lens or a grating.

At least one of the first channel separation element and the second channel separation element may be configurable. At least one of a position and an orientation of the detector segments of the first segmented detector and the second segmented detector may be configurable.

Further embodiments, features, and advantages of the subject matter of the present disclosure, as well as the structure and operation of the various embodiments, are described in detail below with reference to the accompanying drawings.

### BRIEF DESCRIPTION OF THE DRAWING

The accompanying drawings, which are incorporated herein and form part of this specification, illustrate some embodiments and, together with the verbal description, further serve to explain the principles of the embodiments and to enable a person skilled in the relevant art to make and use the embodiments.

FIG. 1 is a schematic, not to scale, diagram of an overall broad conception of a photolithography system.

FIG. 2 is a schematic diagram of an alignment apparatus according to some embodiments.

FIG. 3 schematically depicts a form of an alignment mark that may be provided on a substrate according to some embodiments.

FIG. 4 schematically depicts a form of an alignment mark that may be provided on a substrate according to some embodiments.

FIG. 5 is a diagram, not to scale, of a system for simultaneous capture of polarization channel intensity information for two different polarizations in accordance with an aspect of an embodiment.

FIG. 6 is a diagram, not to scale, of a system for simultaneous capture of polarization channel intensity information for two different polarizations in accordance with another aspect of an embodiment.

FIG. 7 is a diagram, not to scale, of a system for simultaneous capture of polarization channel intensity information for two different polarizations in accordance with another aspect of an embodiment.

FIG. 8 is a perspective view of an example of a segmented optical wedge such as might be used in various embodiments.

FIG. 9 is a diagram, not to scale, of a system for simultaneous capture of color channel intensity information for two different spectral distributions in accordance with another aspect of an embodiment

FIG. 10 is a perspective view of an example of a segmented lens array such as might be used in various embodiments.

FIG. 11 is a diagram, not to scale, of a system for simultaneous capture of polarization channel intensity information for two different polarizations in accordance with an aspect of an embodiment.

FIG. 12A is a side view of a segmented detector such as may be used in the arrangement of FIG. 11 according to an aspect of an embodiment.

FIG. 12B is a side view of a segmented detector such as may be used in the arrangement of FIG. 11 according to an aspect of an embodiment.

Further features and advantages of the disclosed subject matter, as well as the structure and operation of various embodiments of the disclosed subject matter, are described in detail below with reference to the accompanying drawings. It is noted that the applicability of the disclosed subject matter is not limited to the specific embodiments described herein. Such embodiments are presented herein for illustrative purposes only. Additional embodiments will be apparent to persons skilled in the relevant art based on the teachings contained herein.

### DETAILED DESCRIPTION

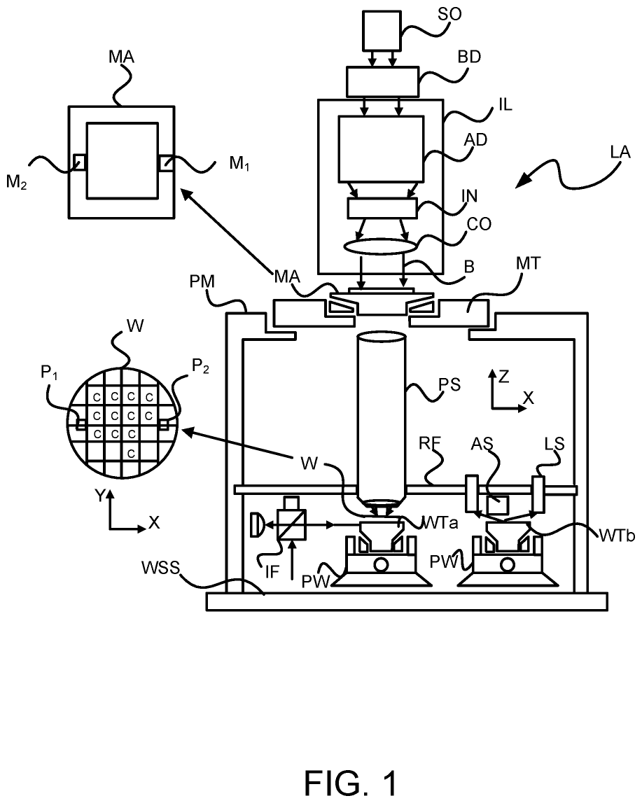

As an introduction, FIG. 1 schematically depicts an embodiment of a lithographic apparatus LA that may be associated with the present systems. The lithographic apparatus LA comprises an illumination system (illuminator) IL configured to condition a radiation beam B. The terms “radiation” and “beam” used herein encompass all types of electromagnetic radiation, including ultraviolet (UV) or deep ultraviolet (DUV) radiation (e.g. having a wavelength of 365, 248, 193, 157 or 126 nm) and extreme ultraviolet (EUV) radiation (e.g. having a wavelength in the range of 5-20 nm), as well as particle beams, such as ion beams or electron beams.

The lithographic apparatus LA also comprises a support structure (e.g. a mask table) MT constructed to support a patterning device (e.g. a mask) MA and connected to a first positioner PM configured to accurately position the patterning device in accordance with certain parameters; one or more substrate tables (e.g. a wafer table) WT (in the example, two wafer tables, WTa and WTb) configured to hold a substrate (e.g. a resist-coated wafer) W. Each wafer table is mechanically coupled to a respective positioner PW configured to accurately position the substrate on a wafer support surface WSS in accordance with certain parameters.

The lithographic apparatus LA also comprises a projection system (e.g. a refractive projection lens system) PS configured to project a pattern imparted to the radiation beam B by patterning device MA onto a target portion C (e.g. comprising one or more dies and often referred to as fields) of the substrate W. The projection system is supported on a reference frame RF.

As depicted, the apparatus is of a transmissive type (e.g. employing a transmissive mask). Alternatively, the apparatus may be of a reflective type (e.g. employing a programmable mirror array of a type as referred to above or employing a reflective mask).

The illuminator IL receives a beam of radiation from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD comprising, for example, suitable directing mirrors and/or a beam expander. In other cases, the source may be an integral part of the apparatus, for example when the source is a mercury lamp. The source SO and the illuminator IL, together with the beam delivery system BD if required, may be referred to as a radiation system. If the radiation source is of the type that produces EUV radiation then generally reflective optics will be used.

The illuminator IL may comprise an adjuster AD configured to adjust the (angular/spatial) intensity distribution of the beam. In addition, the illuminator IL generally comprises various other components, such as an integrator IN and a condenser CO. The illumination system may include various types of optical components for directing, shaping, or controlling radiation. Thus, the illuminator IL provides a conditioned beam of radiation B, having a desired uniformity and intensity distribution in its cross section.

The illuminator IL may be operable to alter the polarization of the beam and may be operable to adjust the polarization state of the radiation beam across the entire pupil plane of the illuminator IL using the adjuster AD or a similar component. The polarization state of the radiation beam across the pupil plane of the illuminator IL may be referred to as a polarization mode. The use of different polarization modes may allow greater contrast to be achieved in the image formed on the substrate W. The radiation beam may alternatively be unpolarized.

The illuminator IL may also be arranged to linearly polarize the radiation beam such that the polarization direction of the radiation beam may vary across a pupil plane of the illuminator IL, i.e. the polarization direction of radiation may be different in different regions in the pupil plane of the illuminator IL. The polarization state of the radiation may be chosen in dependence on the illumination mode.

The support structure MT supports the patterning device using mechanical, vacuum, electrostatic, or other clamping techniques to hold the patterning device. The term “patterning device” used herein should be broadly interpreted as referring to any device that can be used to impart a pattern to a target portion of the substrate.

The lithographic apparatus may be of a type having two or more substrate tables WTa and WTb, as shown. The lithographic apparatus may be of a type having two or more patterning device tables. The lithographic apparatus may be of a type having a substrate table WTa and a table WTb below the projection system without a substrate that is dedicated to, for example, facilitating measurement, and/or cleaning, etc. In such “multiple stage” machines, the additional tables may be used in parallel, or preparatory steps may be carried out on one or more tables while one or more other tables are being used for exposure. For example, alignment measurements using an alignment sensor AS and/or level (height, tilt, etc.) measurements using a level sensor LS may be made on a wafer on one wafer table preparatory to exposure while a wafer on another wafer table is being exposed.

The lithographic apparatus may also be of a type wherein at least a portion of the substrate may be covered by a liquid having a relatively high refractive index, e.g. water, to fill a space between the projection system and the substrate.

In operation of the lithographic apparatus, the radiation beam B is conditioned and provided by the illumination system IL. The radiation beam B is incident on the patterning device (e.g., mask) MA, which is held on the support structure (e.g., mask table) MT, and is patterned by the patterning device. Having traversed the patterning device MA, the patterned radiation beam B passes through the projection system PS, which focuses the beam onto a target portion C of the substrate W. With the aid of its respective positioner PW and position sensor IF (e.g. an interferometric device, linear encoder, 2-D encoder or capacitive sensor), the wafer table WTa or WTb can be moved accurately, e.g. to position different target portions C in the path of the patterned radiation beam B. Similarly, another positioner and another position sensor (which are not explicitly depicted in FIG. 1) can be used to accurately position the patterning device MA with respect to the path of the radiation beam B, e.g. after mechanical retrieval from a mask library, or during a scan.

Patterning device MA and substrate W may be aligned using patterning device alignment marks M1, M2 and substrate alignment marks P1, P2. Although the substrate alignment marks as illustrated occupy dedicated target portions, they may be located in spaces between target portions (scribe-lane alignment marks). Similarly, in applications in which more than one die is provided on the patterning device MA, the patterning device alignment marks may be located between the dies.

The substrate referred to herein may be processed, before or after exposure, for example, in a track (a tool that typically applies a layer of resist to a substrate and develops the exposed resist) or a metrology or inspection tool. Where applicable, the disclosure herein may be applied to such and other substrate processing tools. Further, the substrate may be processed more than once, for example in order to create a multi-layer IC, so that the term “substrate” as used herein may also refer to a substrate that already includes one or more processed layers.

In the alignment sensor, an incident plane wave of light strikes the alignment mark causing both positive and negative reflected diffraction orders. The zero order is removed with a physical stop in the alignment sensor, and the diffracted positive and negative orders interfere with each other causing a sinusoidal intensity signal. From this sinusoidal intensity signal, the alignment position is calculated from the phase of the Fourier transform of the intensity signal. When there is no mark asymmetry, the phase of the positive orders is equal to the phase of the negative orders, and the interference of the positive and negative orders does not cause any alignment position deviation (APD). However, when there is mark asymmetry, the phases of the positive and negative orders are not equivalent, and this phase difference causes an APD error. This phase difference is wavelength and polarization dependent which leads to each wavelength and polarization channel measuring a different APD.

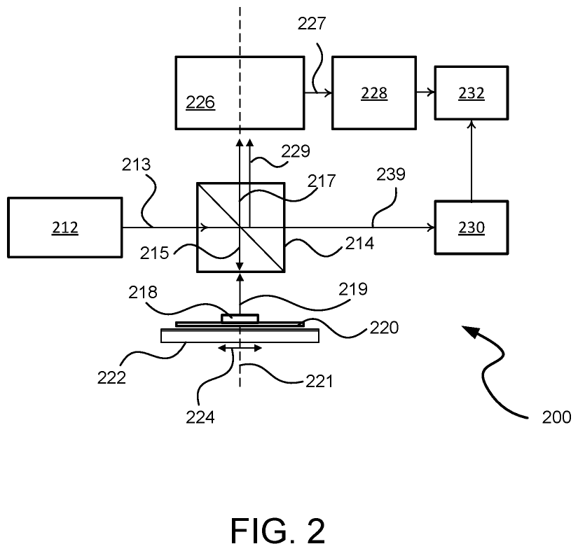

FIG. 2 is a schematic diagram of an alignment apparatus 200 that may be implemented as a part of lithographic apparatus LA according to some embodiments. In some embodiments, alignment apparatus 200 may be configured to align a substrate (e.g., substrate W of FIG. 1) with respect to a patterning device (e.g., patterning device MA of FIG. 1). Alignment apparatus 200 may be further configured to detect positions of alignment marks on the substrate and to align the substrate with respect to the patterning device or other components of lithographic apparatus LA using the detected positions of the alignment marks.

In some embodiments, alignment apparatus 200 may include an illumination system 212, a beam splitter 214, an interferometer 226, a detector 228, a beam analyzer 230, and a processor 232. Illumination system 212 may be configured to provide a radiation beam 213. In some embodiments, beam splitter 214 may be configured to receive radiation beam 213 and split radiation beam 213 into at least two radiation sub-beams. For example, radiation beam 213 may be split into radiation sub-beams 215 and 217, as shown in FIG. 2. Beam splitter 214 may be further configured to direct radiation sub-beam 215 onto a substrate 220 placed on a stage 222. In one example, the stage 222 is movable along direction 224. Radiation sub-beam 215 may be configured to illuminate an alignment mark or a target 218 located on substrate 220.

In some embodiments, beam splitter 214 may be further configured to receive diffraction radiation beam 219 and split diffraction radiation beam 219 into at least two radiation sub-beams, according to an embodiment. Diffraction radiation beam 219 may be split into diffraction radiation sub-beams 229 and 239, as shown in FIG. 2.

It should be noted that even though beam splitter 214 is shown to direct radiation sub-beam 215 towards alignment mark or target 218 and to direct diffracted radiation sub-beam 229 towards interferometer 226, the disclosure is not so limiting. It would be apparent to a person skilled in the relevant art that other optical arrangements may be used to obtain the similar result of illuminating alignment mark or target 218 on substrate 220 and detecting an image of alignment mark or target 218.

As illustrated in FIG. 2, interferometer 226 may be configured to receive radiation sub-beam 217 and diffracted radiation sub-beam 229 through beam splitter 214. In an example embodiment, diffracted radiation sub-beam 229 may be at least a portion of radiation sub-beam 215 that has interacted with (e.g., been reflected from) alignment mark or target 218. In an example of this embodiment, interferometer 226 comprises any appropriate set of optical elements, for example, a combination of prisms that may be configured to form two images of alignment mark or target 218 based on the received diffracted radiation sub-beam 229. It should be appreciated that a good quality image need not be formed, but that the features of alignment mark 218 should be resolved. Interferometer 226 may be further configured as an SRI to rotate one of the two images with respect to the other of the two images 180° and recombine the rotated and unrotated images interferometrically.

In some embodiments, detector 228 may be configured to receive the recombined image via interferometer signal 227 and detect interference as a result of the recombined image when alignment axis 221 of alignment apparatus 200 passes through a center of symmetry (not shown) of alignment mark or target 218. Such interference may be due to alignment mark or target 218 being 180° symmetrical, and the recombined image interfering constructively or destructively, according to an example embodiment. Based on the detected interference, detector 228 may be further configured to determine a position of the center of symmetry of alignment mark or target 218 and consequently, detect a position of substrate 220. According to an example, alignment axis 221 may be aligned with an optical beam perpendicular to substrate 220 and passing through a center of image rotation of the interferometer 226. Detector 228 may be further configured to estimate the positions of alignment mark or target 218 by implementing sensor characteristics and interacting with wafer mark process variations.

In a further embodiment, detector 228 determines the position of the center of symmetry of alignment mark or target 218 by performing one or more of the following measurements:
measuring position variations for various wavelengths (position shift between colors);
measuring position variations for various orders (position shift between diffraction orders); and
measuring position variations for various polarizations (position shift between polarizations).

This data may, for example, be obtained with any type of alignment sensor, for example, the above-described SMASH sensor, as described in U.S. Pat. No. 6,961,116 that employs an SRI with a single detector and four different wavelengths, and extracts the alignment signal in software, or the above-described ATHENA sensor as described in U.S. Pat. No. 6,297,876, which directs each of seven diffraction orders to a dedicated detector, or the sensor described in U.S. Pat. No. 10,508,906 which uses multiple polarizations per available signal (color). See also U.S. Pat. No. 10,962,887, issued Mar. 30, 2021, and titled “Lithographic Method” and H. Megens et al., “Holistic feedforward control for the 5 nm node and beyond,” Optical Microlithography XXXII, Proc. of SPIE Vol. 10961 109610K, doi: 10.1117/12.2515449.

In some embodiments, beam analyzer 230 may be configured to receive and determine an optical state of diffracted radiation of sub-beam 239. The optical state may be a measure of beam wavelength, polarization, or beam profile. Beam analyzer 230 may be further configured to determine a position of stage 222 and correlate the position of stage 222 with the position of the center of symmetry of alignment mark or target 218. As such, the position of alignment mark or target 218 and, consequently, the position of substrate 220 may be accurately known with reference to stage 222. Alternatively, beam analyzer 230 may be configured to determine a position of alignment apparatus 200 or any other reference element such that the center of symmetry of alignment mark or target 218 may be known with reference to alignment apparatus 200 or any other reference element. Beam analyzer 230 may be a point or an imaging polarimeter with some form of wavelength-band selectivity. In some embodiments, beam analyzer 230 may be directly integrated into alignment apparatus 200 or connected via fiber optics of several types: polarization preserving single mode, multimode, or imaging, according to other embodiments.

In some embodiments, an array of detectors (not shown) may be connected to beam analyzer 230. For example, detector 228 may be an array of detectors. For the detector array, a number of options are possible, including multimode fibers, discrete pin detectors per channel, or CCD or CMOS (linear) arrays. The use of a bundle of multimode fibers enables any heat dissipating elements to be located remotely to promote stability. Discrete PIN detectors offer a large dynamic range but each needs separate its own respective pre-amplifier. The number of PIN detectors that can be used is therefore limited. CCD linear arrays offer many elements that may be read-out at high speed and are especially of interest if phase-stepping detection is used.

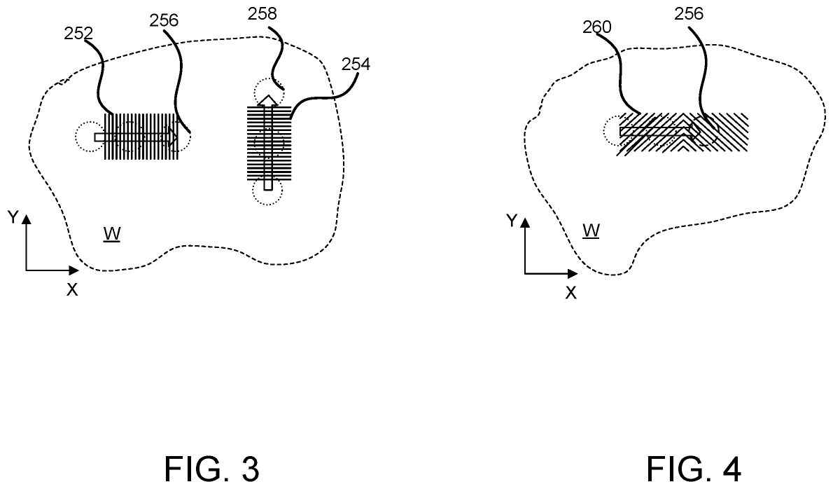

FIG. 3 shows examples of marks 252, 254, that may be provided on substrate W for the measurement of X-position alignment and Y-position alignment respectively. Each mark in this example comprises a series of bars formed in a process layer applied to or etched into a substrate W. The bars are regularly spaced and act as grating lines so that the mark may be regarded as a diffraction grating with a sufficiently well-known spatial period (pitch). The bars on the X-direction mark 252 are parallel to the Y-axis to provide periodicity in the X direction, while the bars of the Y-direction mark 254 are parallel to the X-axis to provide periodicity in the Y direction. The circle 256 represents the illumination spot, i.e., the effective grating area for a given illumination spot position.

FIG. 4 shows a design for a bidirectional fine (“BF”) alignment mark 260 for use with a similar alignment measurement system, whereby X-position alignment and Y-position alignment can be obtained through a single optical scan with the illumination spot 256. The mark 260 has bars arranged at 45 degrees to both the X-and Y-axes. The use of such modified marks 260 for alignment measurements may be performed using the techniques described in U.S. Pat. No. 8,208,121, issued Jun. 26, 2012, and titled “Alignment Mark and a Method of Aligning a Substrate Comprising such an Alignment Mark.” A BF alignment mark has typical dimensions of 160 μ by 40 μ. Another type of alignment mark that can be used is a combined bidirectional (“CB”) mark with typical dimensions of 40 μ by 50 μ.

In general, the alignment sensor is configured to determine the position of such alignment targets having a periodic structure by delivering radiation in multiple intensity channels. See U.S. Pat. No. 10,466,601, issued Nov. 5, 2019, and titled “Alignment Sensor for Lithographic Apparatus.” The radiation beams output by the arrangement of optical components may be coupled into a delivery element which may be an optical multicore fiber. Each radiation beam is coupled into a different physical channel of the delivery element, i.e. into a different core of the multicore fiber.

More specifically, in a known arrangement an illumination source may comprise four individual sources to provide radiation with four wavelengths, e.g., green (G), red (R), near infrared (N) and far infrared (F). The radiation at these four different wavelengths is referred to as four colors of radiation herein without regard to whether they are in the visible or non-visible parts of the electromagnetic spectrum. All the sources are linearly polarized, with the G and N radiation being oriented in the same direction as one another, and the R and F radiation being polarized in the same direction as one another and orthogonally to the G and N polarization.

The four colors are transported by polarization-maintaining fibers to a multiplexer, where they are combined into a single combined beam that comprises all four colors. The combined beam is focused to a narrow beam which interacts with (e.g., is reflected and/or diffracted by) the periodic structure (e.g. grating) of the alignment mark formed on the substrate. At least some of the interacted beam, that is, at least some of the portion of the beam that has interacted with the alignment mark, may be collected by an objective.

The interacted beam carrying alignment information is then transported to an SRI. The SRI splits the information-carrying beam into two parts with orthogonal polarization, rotates these parts about the optical axis by 180° relative to one another, and combines them into an outgoing radiation beam. The outgoing radiation beam exits the SRI, after which a beam splitter splits the optical signal into two paths. One path contains the sum of the two rotated fields, and the other contains the difference.

In this example one polarization for illumination in each color is used. Measurements with two polarizations per color could be made, by changing the polarization between readings (or by time division multiplexing within a reading).

The radiation for each path is collected by a respective collector lens assembly. The radiation then goes through an aperture that eliminates most of the radiation from outside the spot on the substrate. A multimode fiber transports the collected radiation of each path to a respective demultiplexer. The demultiplexer splits each path in the original four colors, so that a total of eight optical signals are delivered to the detectors. A processing unit receives the intensity waveforms from the eight detectors and processes them to provide a position measurement.

It is to be noted that the alignment sensor may comprise optical components and elements in addition to those described above. For example, the alignment sensor may comprise one or several beam-shaping components, such as polarizers, quarter-waveplates, or half-waveplates.

According to an aspect of an embodiment the use of channel separation elements, e.g., wedges may be combined with the use of multicore fibers or segmented detectors for enhanced detection of intensity channels. In one embodiment, the light rays for detection pass through a segmented wedge and a lens. At the focus of the lenses a number of spots corresponding to the number of segments in the wedge appear. For example, if the wedge has four segments or quadrants, then four spots corresponding to the four quadrants of the wedge appear.

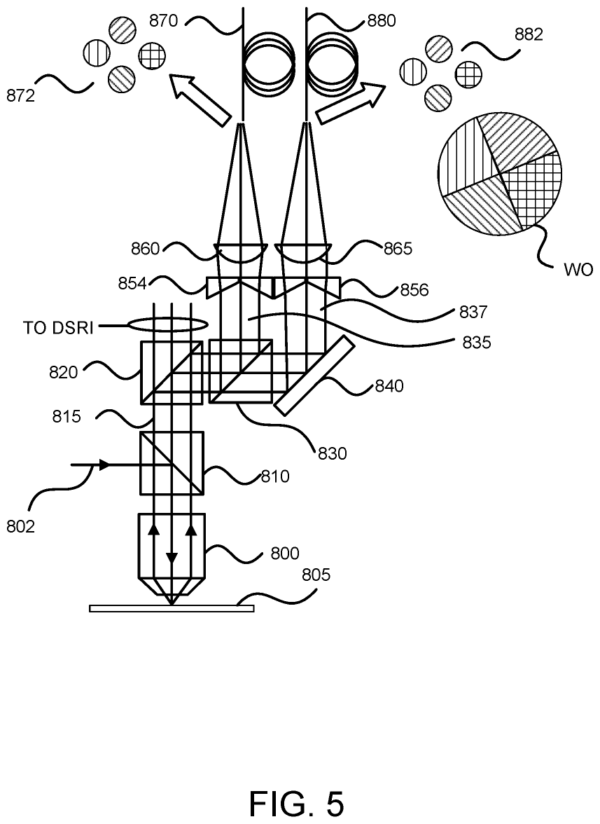

In accordance with one aspect of an embodiment, as shown in FIG. 5, radiation 802 from an illumination source (not explicitly shown in FIG. 5) interacts with a mark 805 which may be an alignment mark. An objective 800 receives the radiation 815 that has interacted with the alignment mark 805. The interacted radiation 815 passes through a spot mirror 810.

In other words, radiation 815 that has interacted with the mark 805 is picked up by the objective 800 and collimated into an information-carrying beam which propagates to a dual self-referencing interferometer (DSRI) (not explicitly shown in FIG. 5) of the type disclosed in U.S. Pat. No. 6,961,116, referred to above. The DSRI processes the portion of the beam 815 that it receives and outputs separate beams for different wavelengths. The respective intensities of the separate beams are sensed by sensors. Intensity signals from individual sensors are provided to a processor. By a combination of optical processing and computational processing, values for X- and Y-position on the substrate relative to the frame MF are obtained.

It may be beneficial for some implementations, however, to split off some of the radiation that has interacted with the mark and process that radiation differently to obtain additional measurement information. Thus, in accordance with an aspect of an embodiment, as shown in FIG. 5, a nonpolarizing beam splitter (NBS) 820 splits the beam 815 into two parts. One portion of the split beam continues on to a DSRI for alignment analysis as described above. The other portion of the split beam passes through a polarizing beam splitter (PBS) 830.

The PBS 830 functions as a beam separation element that splits the beam into two beams of differing optical characteristics, in this example polarizations, thus creating a first polarization arm or channel 835 and a second polarization arm or channel 837. Radiation in the first polarization channel 835 passes through a first channel separation element 854, which may be realized as an optical wedge. As described more fully below, however, one of ordinary skill in the art will appreciate that for all embodiments the channel separation elements may be realized using components other than transmissive optical wedges so long as those components perform the function of creating spatial separation of radiation passing through them. Other examples include reflective optical wedges, gratings, and segmented lens arrays, among others. The orientation of the first channel separation element 854 realized as a four segment optical wedge is shown in the inset WO (wedge orientation), with each segment or quadrant of the wedge being assigned a different pattern.

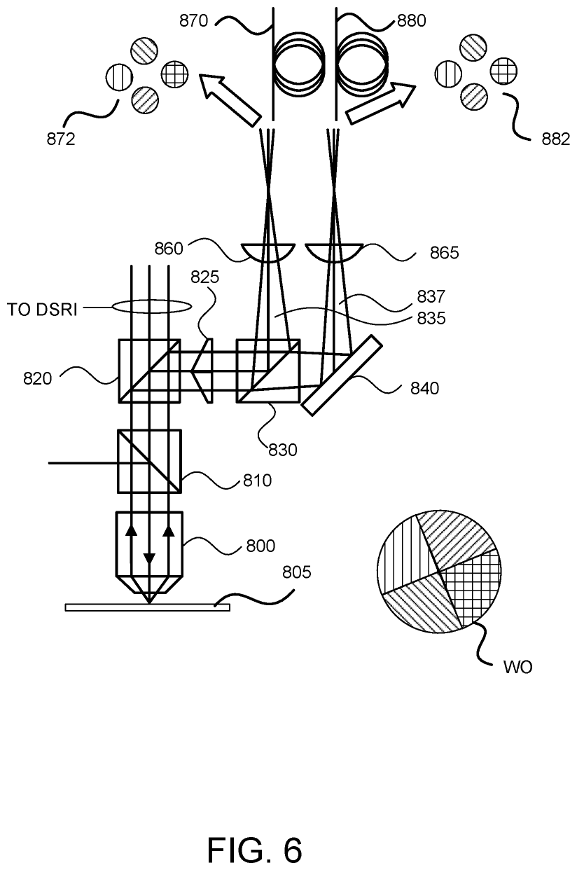

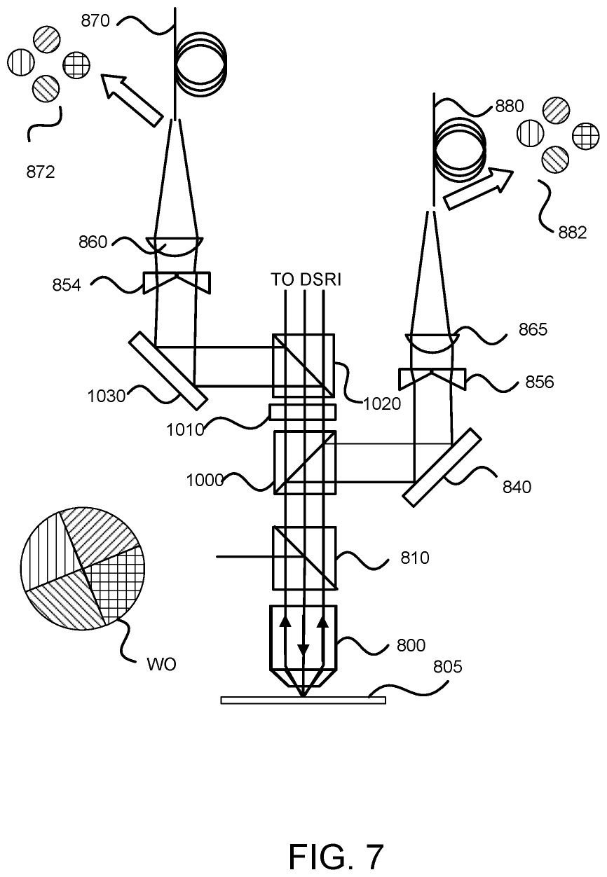

The radiation in the second channel 837 is directed by a folding mirror 840 through a second channel separation element 856 which may also be realized as an optical wedge. In the example shown, the optical wedges are divided into four segments but a different number of segments could be used, depending on the location of the diffracted orders, and if it is desired to separate lower diffraction orders from higher diffraction orders. The orientation of the second channel separation element 856 realized as a four segment optical wedge is also shown in the inset WO, with each quadrant of the wedge being assigned a different pattern. The same applies to the inset WO shown in FIG. 6 and FIG. 7.

The channel separation elements 854 and 856 create spatial separation of the radiation passing through them. The spots of radiation may be regarded as channel constituents which passing through the optical channel separation element 854 and go through a lens 860. The channel constituents that pass through channel separation element 856 are focused by a lens 865. The intensities of the channel constituents are then separately sensed. In the example shown, the lens 860 and the lens 865 respectively comprise optical elements arranged to focus their respective channel constituents, i.e., spots of radiation. It will be understood for this and other embodiments that these optical elements may be made up of one lens or by more than one lens.

In the example of FIG. 5, a multicore fiber 870 which may contain multimode fiber cores, single mode fiber cores, or both, is placed at the focus of the lens 860. The lens 865 focuses the spots of radiation it receives onto a multicore fiber 880 which also may contain multimode fiber cores, single mode fiber cores, or both. The spots are thus optically coupled into respective cores of the multicore fibers. According to an aspect of this embodiment, the multicore fibers convey the radiation to remote detectors that generate signals based on the radiation. The signals are then processed to derive alignment information.

One of ordinary skill in the art will appreciate that the channel separation elements disclosed herein may be configurable. For example, they may be movable, i.e., translatable in any direction such as parallel to or orthogonal to a beam passing through them. One of ordinary skill in the art will also appreciate that the channel separation elements disclosed herein may be configurable in the sense of being rotatable. For example, they may be rotatable around an axis parallel to or orthogonal to a beam passing through them.

One of ordinary skill in the art will also appreciate that the multicore fibers implemented as disclosed herein may be similarly configurable. For example, the portion of the multicore fiber arranged to receive the spots of radiation, i.e., the receiving end may be movable, i.e., translatable in any direction such as parallel to or orthogonal to a beam reaching it. One of ordinary skill in the art will also appreciate that the receiving ends of the multicore fibers disclosed herein may be configurable in the sense of having different possible orientations. For example, they may be rotatable around an axis parallel to or orthogonal to the radiation reaching them.

The number of cores in each of the multicore fibers will in general correspond to the number of segments in the optical wedges. As mentioned, as is true for all multicore fibers described herein, they may contain multimode fiber cores, single mode fiber cores, or both. Thus, in the example shown in the figure, each of the multicore fibers 870, 880 contains four cores. Multicore fiber 870 receives radiation 872 having one polarization state and the other multicore fiber 880 receives radiation 882 having another polarization state.

The four spots of the radiation 872 respectively correspond to the similarly patterned segment of the optical wedge in the inset WO when the channel separation element 854 is implemented as such a wedge. The four spots of the radiation 882 respectively correspond to the similarly patterned segment of the optical wedge in the inset WO when the channel separation element 856 is implemented as such a wedge. The same applies to the inset WO shown in FIG. 6 and FIG. 7. The multicore optical fibers convey the radiation they receive to sensors coupled to analyzers that extract alignment information from the respective intensities of the spots. This makes it possible to simultaneously read out information for each of the two polarization states by using two wedges.

FIG. 6 shows an arrangement similar to that of FIG. 5 except that the embodiment of FIG. 6 uses only a single wedge positioned between the NBS 820 and the PBS 830. Thus, the arrangement of FIG. 6 includes an objective 800 which receives radiation that has interacted with a mark 805. The radiation from the objective 800 passes through a spot mirror 810 which blocks out radiation which is not used for determining alignment.

The radiation from the spot mirror 810 propagates to the NBS 820. One split portion of the radiation from NBS 820 goes towards a DSRI. The other portion of the radiation passes through the optical wedge 825 and then on to the PBS 830. Thus, spatial separation of the channels in each beam is achieved prior to the radiation being divided into two separate beams permitting the use of only a single wedge. One beam from the PBS 830, first channel radiation 835, propagates through lens 860 to a point where it is coupled into the multicore fiber 870. Similarly, the other beam from the PBS 830, second channel radiation 837, is turned by a turning mirror 840 to pass through the lens 865 and then coupled to the multicore optical fiber 880. In the focus of the lenses four spots will appear corresponding with the four quadrants of the wedge 825. Thus, this embodiment makes it possible to read out both polarization states with the use of a single wedge.

Various additional alternative designs are possible. For example, it is possible to have an arrangement in which there are two separate polarization-resolved arms. Such an arrangement is shown in FIG. 7. In the embodiment shown in FIG. 7, radiation from the spot mirror 810 is split by PBS 1000. One part of the split radiation is turned by a turning mirror 840 to an optical wedge 856 and is focused by a lens 885 to be coupled into a multicore fiber 880. The other portion of the radiation split by PBS 1000 passes through a HWP 1010 which rotates its polarization by 90 degrees. The radiation with a now-rotated polarization then passes to a second PBS 1020 which again splits the radiation. Some of the radiation is directed to a DSRI. The other portion of the radiation is directed to a turning mirror 1030 through an optical wedge 854 and then through a lens 860 to be coupled into a multicore fiber 870.

In these embodiments the diffracted orders are picked up with an NBS between the spot mirror and the DSRI. The reflected part of the beam from the NBS is reflected into an “intensity channels” arm where a polarizing beam splitter (PBS) filters the polarization channels. Each polarization channel is transmitted through an optical wedge such that each segment gets a different beam direction.

Both polarization channels are then focused using respective lenses. Because each segment of diffracted orders has been spatially separated, that is, has a different angle, the focus on the fiber contains four spots. Each spot is coupled to its own respective fiber core, which in some embodiments may connect in a known way to a demultiplexer (DMUX). Ultimately signals are developed which are based on the intensity of the respective spots, and these signals are processed to obtain alignment information.

As will be appreciated, according to an aspect of an embodiment, the design is compact in terms of the relatively small number of components used. It also relies only on the use of passive fixed elements and requires no switchable components or actuators.

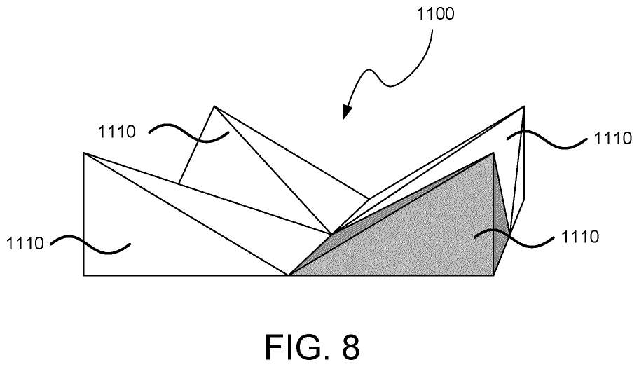

The use a segmented wedge to create the spatial separation of the diffracted orders in the pupil provides the advantage that such a wedge typically introduces only a small amount of dispersion. One possible implementation of such a segmented wedge is shown in FIG. 8. As shown, the segmented optical wedge 1100 is made up of four similar segments 1110 arranged symmetrically to divide the pupil into four separate regions. Such a segmented optical wedge 1100 may be fabricated, for example, by gluing the four segments together. The principles elucidated herein are not limited to systems which use four segments and can be applied as well to systems using a different number and/or orientation and/or shape of segments to, for example, capture separate higher orders. The number and position of fiber cores should in general scale with the number of segments. For some embodiments the segments have the same dimensions and are homogeneously distributed over the pupil. It will be appreciated that this may not be necessary for some applications.

In the above description the optical wedges used in the exemplary embodiments are transmissive. It will be appreciated that reflective optical wedges could be used instead, with appropriate modifications to ray paths and the placement of other components.

For embodiments in which dispersion is exploited, the spatial separation of the diffraction orders could be performed, for example, with a grating, resulting in a deflection angle exhibiting a strong dependence on wavelength.

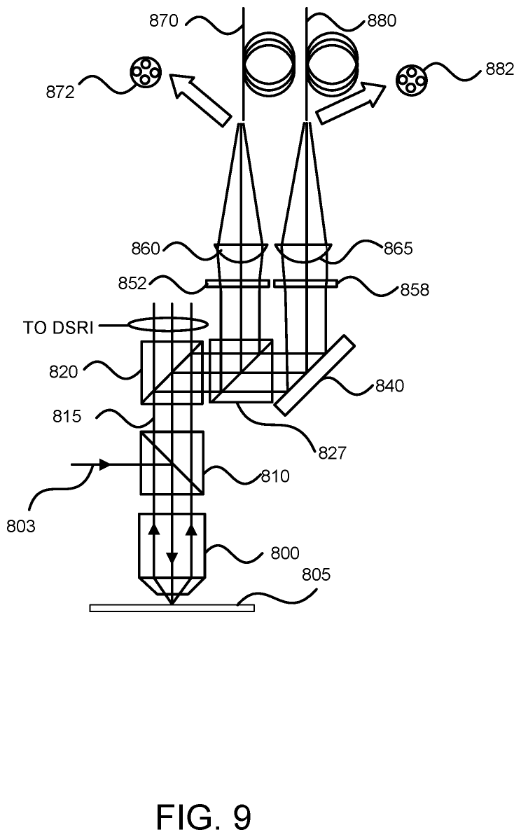

While the above examples use polarization filtering to create separate channels, it will be appreciated that channels can also be created using color filtering. This is shown in FIG. 9. The incoming beam 803 is made up of four colors, e.g., red, green, near infrared, and far infrared. Spectral splitting element 827 splits the incoming radiation into two beams (color channels) with differing spectral characteristics. Spectral splitting element 827 may be, for example, a spectral beam splitter. Channel separation elements 852 and 858 may be gratings that create physical separation for different colors. In such case, it may be advantageous for some applications to use multicore fibers having more than four cores.

Another advantage of the exemplary embodiments described above is that they can be implemented using a relatively smaller number of DMUX modules.

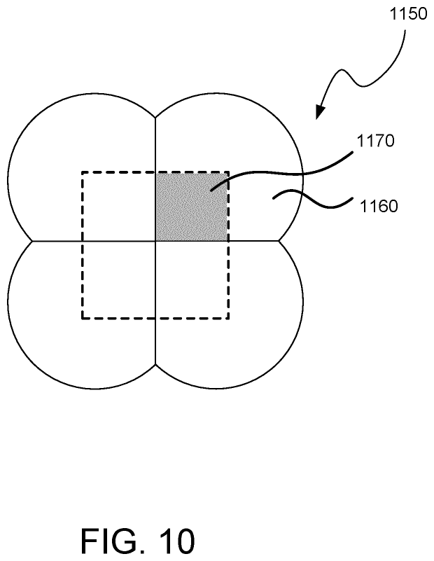

As another alternative to the use of a combination of an optical wedge and lens, it will be appreciated that a segmented lens array may be used, as shown, for example, in FIG. 10. There is shown a segmented lens array 1150 implemented as a 2×2 segmented lens array such as may be used in partitioned aperture wavefront imaging (a PAW lens). In the example shown the segmented lens array 1150 is a quatrefoil lens made up of four lenses 1160 that are cut off-axis and glued together. The images are obtained foreach quadrant from the portion 1170 of the lens 1160 close to its intersection with the other lenses.

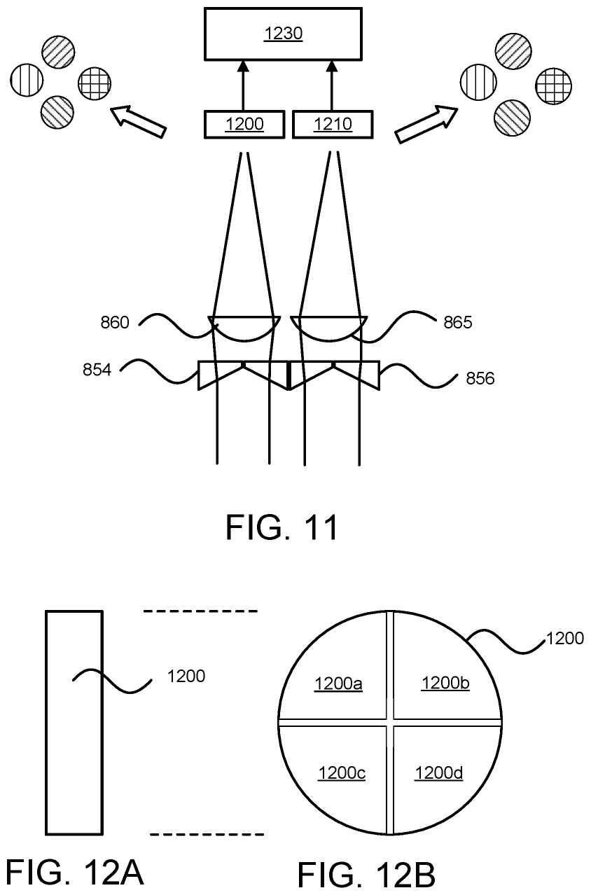

In the embodiments described above, the lenses such as lenses 860 and 865 focus spots of radiation onto a respective multicore fiber for remote detection. According to another aspect of an embodiment, the spots of radiation may be focused on respective segments of a segmented detector such as a four segment detector also referred to as a quadrant detector or simply a quad detector. Such an arrangement is shown in FIG. 11 where the respective sets of spots are each focused on a segmented detector. Specifically, the four spots focused by the lens 860 are focused on respective segments of a segmented detector 1200 and the four spots focused by the lens 865 are focused on respective segments of a segmented detector 1210. The segmented detectors 1200 and 1210 develop signals indicative of the intensity of the spot on each segment. These signals are provided to a processor 1230 which uses the signals to develop alignment information.

FIG. 12A is a side view of the segmented detector 1200 and FIG. 12B is a plan view of the segmented detector 1200. As can be seen in FIG. 12B, the segmented detector 1200 may have four segments, 1200a, 1200b, 1200c, and 1200d. It will be understood that the rotational orientation of the segmented detectors 1200 and 1210 is configurable such that either or both of the segmented detectors 1200 and 1210 may be rotated to align the segments with respective spots of radiation. In some embodiments the position of the segmented detectors 1200 and 1210 is configurable such that either or both of the segmented detectors 1200 and 1210 may be moved laterally to align the segments with respective spots of radiation or axially to adjust the focus of the lenses on the plane of the detectors.

Embodiments of the present invention may partially be implemented in hardware, firmware, software, or any combination thereof. Embodiments of the present invention may also be partially implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM), random access memory (RAM), magnetic disk storage media, optical storage media; flash memory devices, electrical, optical, acoustical, or other forms of propagated signals (e.g., carrier waves, infrared signals, digital signals, etc.), and others.

The above description includes examples of multiple embodiments. It is, of course, not possible to describe every conceivable combination of components or methodologies for purposes of describing the aforementioned embodiments, but one of ordinary skill in the art may recognize that many further combinations and permutations of various embodiments are possible. Accordingly, the described embodiments are intended to embrace all such alterations, modifications and variations that fall within the spirit and scope of the appended claims. Furthermore, to the extent that the term “includes” is used in either the detailed description or the claims, such term is intended to be inclusive in a manner similar to the term “comprising” as “comprising” is construed when employed as a transitional word in a claim. Furthermore, although elements of the described aspects and/or embodiments may be described or claimed in the singular, the plural is contemplated unless limitation to the singular is explicitly stated. Additionally, all or a portion of any aspect and/or embodiment may be utilized with all or a portion of any other aspect and/or embodiment, unless stated otherwise.

It is to be appreciated that the Detailed Description section, and not the Summary and Abstract sections, is intended to be used to interpret the claims. The Summary and Abstract sections may set forth one or more but not all exemplary embodiments of the present invention as contemplated by the inventor(s), and thus, are not intended to limit the present invention and the appended claims in any way.

The present invention has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The embodiments can be further described using the following clauses.
1. A metrology device comprising:
a beam separation element arranged to receive measurement radiation that has interacted with a mark and to cause a first fraction of the measurement radiation to propagate in a first channel and to cause a second fraction of the measurement radiation to propagate in a second channel, the second fraction having a different optical property than the first fraction;
a first channel separation element arranged in the first channel to spatially separate a plurality of first channel constituents of the first fraction;
a first channel optical element arranged to focus the first channel constituents;
a first multicore fiber having a plurality of cores respectively corresponding to ones of the plurality of first channel constituents, the first multicore fiber having receiving ends arranged at a focal plane of the first channel optical element;
a second channel separation element arranged in the second channel to spatially separate a plurality of second channel constituents of the second fraction;
a second channel optical element arranged to focus the second channel constituents; and
a second multicore fiber having a plurality of cores respectively corresponding to ones of the plurality of second channel constituents, the second multicore fiber having receiving ends arranged at a focal plane of the second channel optical element.
2. The metrology device of clause 1 wherein the optical property is polarization.
3. The metrology device of clause 1 wherein the optical property is color.
4. The metrology device of clause 1 wherein the first channel constituents and the second channel constituents comprise diffraction orders.
5. The metrology device of clause 1 wherein the beam separation element comprises a polarizing beam splitter arranged to receive the measurement radiation and to cause the first fraction of the received radiation having a first polarization to propagate in the first channel and to cause the second fraction of the received radiation having a second polarization to propagate in the second channel.
6. The metrology device of clause 1 wherein the first channel separation element comprises a first segmented optical wedge and the second channel separation element comprises a second segmented optical wedge.
7. The metrology device of clause 6 wherein the first segmented optical wedge and the second segmented optical wedge are transmissive.
8. The metrology device of clause 6 wherein the first segmented optical wedge and the second segmented optical wedge are reflective.
9. The metrology device of clause 1 wherein the first channel separation element comprises a first segmented lens and the second channel separation element comprises a second segmented lens.

10. The metrology device of clause 1 wherein the first channel separation element comprises a first grating and the second channel separation element comprises a second grating.
11. The metrology device of clause 1 wherein the first multicore fiber comprises one of multimode fiber cores, single mode fiber cores, and a combination of multimode fiber cores and single mode fiber cores and the second multicore fiber comprises one of multimode fiber cores, single mode fiber cores, and a combination of multimode fiber cores and single mode fiber cores.
12. The metrology device of clause 1 wherein at least one of the first channel separation element and the second channel separation element is configurable.
13. The metrology device of clause 1 wherein at least one of a position and an orientation of receiving ends of at least one of the first multicore fiber and the second multicore fiber is configurable.
14. A metrology device comprising:
a spatial separation element arranged to receive measurement radiation that has interacted with a mark and to spatially separate constituents of the measurement radiation;
a beam separation element arranged to receive the spatially separated measurement radiation and to cause a first fraction of the spatially separated measurement radiation to propagate in a first channel and to cause a second fraction of the spatially separated measurement radiation to propagate in a second channel, the second fraction having a different optical property than the first fraction;
a first channel optical element arranged to focus the first fraction;
a first multicore fiber having a plurality of cores respectively corresponding to constituents in the first channel arranged at a focal plane of the first channel optical element;
a second channel optical element arranged to focus the second fraction; and
a second multicore fiber having a plurality of cores respectively corresponding to constituents in the second channel arranged at a focal plane of the second channel optical element.
15. The metrology device of clause 14 wherein the optical property is polarization.
16. The metrology device of clause 14 wherein the optical property is color.
17. The metrology device of clause 14 wherein the constituents comprise diffraction orders.
18. The metrology device of clause 14 wherein the beam separation element comprises a polarizing beam splitter arranged to receive the spatially separated measurement radiation and to cause the first fraction of the measurement radiation having a first polarization to propagate in the first channel and to cause the second fraction of the measurement radiation having a second polarization to propagate in the second channel.
19. The metrology device of clause 14 wherein the separation element comprises a segmented optical wedge.
20. The metrology device of clause 19 wherein the segmented optical wedge is transmissive.
21. The metrology device of clause 19 wherein the segmented optical wedge is reflective.
22. The metrology device of clause 14 wherein the channel separation element comprises a segmented lens.

23. The metrology device of clause 14 wherein the channel separation element comprises a grating.
24. The metrology device of clause 14 wherein the first multicore fiber comprises one of multimode fiber cores, single mode fiber cores, and a combination of multimode fiber cores and single mode fiber cores and the second multicore fiber comprises one of multimode fiber cores, single mode fiber cores, and a combination of multimode fiber cores and single mode fiber cores.
25. The metrology device of clause 14 wherein at least one of the first channel separation element and the second channel separation element is configurable.
26. The metrology device of clause 14 wherein at least one of a position and an orientation of receiving ends of at least one of the first multicore fiber and the second multicore fiber is configurable.
27. A metrology device comprising:
a polarizing beam splitter arranged to receive measurement radiation that has interacted with a mark and to cause a first fraction of the measurement radiation having a first polarization to propagate in a first arm and to cause a second fraction of the received radiation having a second polarization to propagate in a second arm;
the first arm comprising a polarizing beam splitter arranged to receive the first fraction and to split off first polarized radiation from the first fraction, first optics arranged to receive the first polarized radiation and to spatially separate and focus the first polarized radiation, and a first multicore fiber arranged at a focal plane of the first optics, and
the second arm comprising second optics arranged to receive the second fraction and to spatially separate and focus the second fraction and a second multicore fiber arranged at a focal plane of the second optics.
28. The metrology device of clause 27 further comprising a polarization rotation element positioned in the first arm between the polarizing beam splitter and the first optics.
29. The metrology device of clause 27 wherein the first optics comprises a first segmented optical wedge and wherein the second optics comprises a second segmented optical wedge.
30. The metrology device of clause 29 wherein the first segmented optical wedge is transmissive.
31. The metrology device of clause 29 wherein the first segmented optical wedge is reflective.
32. The metrology device of clause 27 wherein the first optics comprises a segmented lens.
33. The metrology device of clause 27 wherein the first optics comprises a grating.
34. The metrology device of clause 27 wherein the first multicore fiber comprises one of multimode fiber cores, single mode fiber cores, and a combination of multimode fiber cores and single mode fiber cores and the second multicore fiber comprises one of multimode fiber cores, single mode fiber cores, and a combination of multimode fiber cores and single mode fiber cores.
35. The metrology device of clause 27 wherein at least one of the first channel separation element and the second channel separation element is configurable.
36. The metrology device of clause 27 wherein at least one of a position and an orientation of receiving ends of at least one of the first multicore fiber and the second multicore fiber is configurable.
37. A metrology device comprising:
a beam separation element arranged to receive measurement radiation that has interacted with a mark and to cause a first fraction of the measurement radiation to propagate in a first channel and to cause a second fraction of the measurement radiation to propagate in a second channel, the second fraction having a different optical property than the first fraction;
a first channel separation element arranged in the first channel to spatially separate a plurality of first channel constituents of the first fraction;
a first channel optical element arranged to focus the first channel constituents;
a first segmented detector having a plurality of first detector segments corresponding to ones of the plurality of first channel constituents, the first detector segments being arranged at a focal plane of the first channel optical element;
a second channel separation element arranged in the second channel to spatially separate a plurality of second channel constituents of the second fraction;
a second channel optical element arranged to focus the second channel constituents; and
a second segmented detector having a plurality of second detector segments corresponding to ones of the plurality of second channel constituents, the second detector segments being arranged at a focal plane of the second channel optical element.
38. The metrology device of clause 37 wherein the optical property is polarization.
The metrology device of clause 37 wherein the optical property is color.
40. The metrology device of clause 37 wherein the first channel constituents and the second channel constituents comprise diffraction orders.
41. The metrology device of clause 37 wherein the beam separation element comprises a polarizing beam splitter arranged to receive the measurement radiation and to cause the first fraction of the received radiation having a first polarization to propagate in the first channel and to cause the second fraction of the received radiation having a second polarization to propagate in the second channel.
42. The metrology device of clause 37 wherein the first channel separation element comprises a first segmented optical wedge and the second channel separation element comprises a second segmented optical wedge.
43. The metrology device of clause 42 wherein the first segmented optical wedge and the second segmented optical wedge are transmissive.
44. The metrology device of clause 42 wherein the first segmented optical wedge and the second segmented optical wedge are reflective.
45. The metrology device of clause 37 wherein the first channel separation element comprises a first segmented lens and the second channel separation element comprises a second segmented lens.
46. The metrology device of clause 37 wherein the first channel separation element comprises a first grating and the second channel separation element comprises a second grating.
47. The metrology device of clause 37 wherein at least one of a position and an orientation of the detector segments of at least one of the first segmented detector and the second segmented detector is configurable.

The above described implementations and other implementations are within the scope of the following claims.

1. A metrology device comprising:
a beam separation element arranged to receive measurement radiation that has interacted with a mark and to cause a first fraction of the measurement radiation to propagate in a first channel and to cause a second fraction of the measurement radiation to propagate in a second channel, the second fraction having a different optical property than the first fraction;
a first channel separation element arranged in the first channel to spatially separate a plurality of first channel constituents of the first fraction;
a first channel optical element arranged to focus the first channel constituents;
a first multicore fiber having a plurality of cores respectively corresponding to ones of the plurality of first channel constituents, the first multicore fiber having receiving ends arranged at a focal plane of the first channel optical element;
a second channel separation element arranged in the second channel to spatially separate a plurality of second channel constituents of the second fraction;
a second channel optical element arranged to focus the second channel constituents; and
a second multicore fiber having a plurality of cores respectively corresponding to ones of the plurality of second channel constituents, the second multicore fiber having receiving ends arranged at a focal plane of the second channel optical element.

2. The metrology device of claim 1 wherein the optical property is polarization.

3. The metrology device of claim 1 wherein the optical property is color.

4. The metrology device of claim 1 wherein the first channel constituents and the second channel constituents comprise diffraction orders.

5. The metrology device of claim 1 wherein the beam separation element comprises a polarizing beam splitter arranged to receive the measurement radiation and to cause the first fraction of the received radiation having a first polarization to propagate in the first channel and to cause the second fraction of the received radiation having a second polarization to propagate in the second channel.

6. The metrology device of claim 1 wherein the first channel separation element comprises a first segmented optical wedge and the second channel separation element comprises a second segmented optical wedge.

7. The metrology device of claim 6 wherein the first segmented optical wedge and the second segmented optical wedge are transmissive.

8. The metrology device of claim 6 wherein the first segmented optical wedge and the second segmented optical wedge are reflective.

9. The metrology device of claim 1 wherein the first channel separation element comprises a first segmented lens and the second channel separation element comprises a second segmented lens.

10. The metrology device of claim 1 wherein the first channel separation element comprises a first grating and the second channel separation element comprises a second grating.

11. The metrology device of claim 1 wherein the first multicore fiber comprises one of multimode fiber cores, single mode fiber cores, and a combination of multimode fiber cores and single mode fiber cores and the second multicore fiber comprises one of multimode fiber cores, single mode fiber cores, and a combination of multimode fiber cores and single mode fiber cores.

12. The metrology device of claim 1 wherein at least one of the first channel separation element and the second channel separation element is configurable.

13. The metrology device of claim 1 wherein at least one of a position and an orientation of receiving ends of at least one of the first multicore fiber and the second multicore fiber is configurable.

14. A metrology device comprising:
a spatial separation element arranged to receive measurement radiation that has interacted with a mark and to spatially separate constituents of the measurement radiation;
a beam separation element arranged to receive the spatially separated measurement radiation and to cause a first fraction of the spatially separated measurement radiation to propagate in a first channel and to cause a second fraction of the spatially separated measurement radiation to propagate in a second channel, the second fraction having a different optical property than the first fraction;
a first channel optical element arranged to focus the first fraction;
a first multicore fiber having a plurality of cores respectively corresponding to constituents in the first channel arranged at a focal plane of the first channel optical element;
a second channel optical element arranged to focus the second fraction; and
a second multicore fiber having a plurality of cores respectively corresponding to constituents in the second channel arranged at a focal plane of the second channel optical element.

15. The metrology device of claim 14 wherein the beam separation element comprises a polarizing beam splitter arranged to receive the spatially separated measurement radiation and to cause the first fraction of the measurement radiation having a first polarization to propagate in the first channel and to cause the second fraction of the measurement radiation having a second polarization to propagate in the second channel.
